(19) United States
(12) Patent Application Publication
(10) Pub. No.: US 2019/0344356 A1
(43) Pub. Date: Nov. 14, 2019

(54) CUTTING INSERT AND CUTTING TOOL

(71) Applicant: KYOCERA CORPORATION, Kyoto-shi, Kyoto (JP)

(72) Inventors: Yoshikazu KODAMA, Nobeoka-shi, Miyazaki (JP); Hirotoshi ITOH, Satsumasendai-shi, Kagoshima (JP); Tadashi KATSUMA, Satsumasendai-shi, Kagoshima (JP); Kensaku WATANABE, Satsumasendai-shi, Kagoshima (JP); Kenji KUMAI, Satsumasendai-shi, Kagoshima (JP); Yuusaku SUGAWA, Satsumasendai-shi, Kagoshima (JP)

(21) Appl. No.: 16/461,401

(22) PCT Filed: Nov. 15, 2017
(86) PCT No.: PCT/JP2017/041029

§ 371 Date: May 16, 2019

(30) Foreign Application Priority Data
Nov. 16, 2016 (JP) 2016-223454

(51) Int. Cl. B23B 27/14; B23B 29/02; B23C 5/16; C23C 16/36; C23C 16/34; C23C 16/40

(52) U.S. Cl. CPC B23B 27/14; B23B 29/02; C23C 16/403; C23C 16/36; C23C 16/34; B23C 5/16

(57) ABSTRACT

A cutting insert may include a base member and a coating layer. The base member may include a first and second surface. The coating layer may be located on the base member. The coating layer may include a first layer containing α-aluminum oxide, which is located above the first surface and the second surface. The first layer may include a first region located above the first surface, and a second region located above the second surface. When an angle formed by a normal line of a crystal plane (001) of the α-aluminum oxide in the first layer and a normal line of the surface of the base member is a first inclination angle, a peak of a distribution of the first inclination angle in the first region is located at a lower angle side than a peak of a distribution of the first inclination angle in the second region.

### CROSS-REFERENCE TO RELATED APPLICATIONS

This application is a national stage entry according to 35 U.S.C. 371 of PCT Application No. PCT/JP2017/041029 filed on Nov. 15, 2017, which claims priority to Japanese Application No. 2016-223454 filed on Nov. 16, 2016, which are entirely incorporated herein by reference.

### TECHNICAL FIELD

The present disclosure relates to cutting inserts and cutting tools.

### BACKGROUND

As a cutting insert (hereinafter also referred to simply as an insert) for use in a cutting process, such as a turning process and a milling process, an insert as described in, for example, Japanese Unexamined Patent Publication No. 2005-205586 has been known. The insert described in this patent document may include a coating layer on a surface of a base member composed of cemented carbide or the like. The coating layer may include a titanium carbonitride (TiCN) layer and an aluminum oxide (Al₂O₂) layer.

When an inclination angle distribution is evaluated in terms of inclination angle formed by a normal line of a (001) plane of crystals of aluminum oxide with respect to a normal line of a polished plane surface in the above aluminum oxide layer, a highest peak may exist in an inclination angle segment in a range of 0-10 degrees.

### SUMMARY

In a non-limiting embodiment of the present disclosure, a cutting insert may include a base member and a coating layer. The base member may include a first surface and a second surface adjacent to the first surface. The coating layer may be located on a surface of the base member. The coating layer may include a first layer which is located above the first surface and the second surface and contains α-aluminum oxide. The first layer may include a first region located above the first surface, and a second region located above the second surface. When an angle formed by a normal line of a (001) plane being a crystal plane of the α-aluminum oxide in the first layer and a normal line of the surface of the base member is taken as a first inclination angle, a peak of a distribution of the first inclination angle in the first region may be located at a lower angle side than a peak of a distribution of the first inclination angle in the second region.

In a non-limiting embodiment of the present disclosure, a cutting tool may include a holder and a cutting insert. The holder may include a bar-shaped body extending from a first end toward a second end, and may include a pocket at a side of the first end. The cutting insert may be located at the pocket in the holder.

### BRIEF DESCRIPTION OF THE DRAWINGS

FIG. 1 is a perspective view illustrating a cutting insert (an insert) in a non-limiting embodiment of the present disclosure;

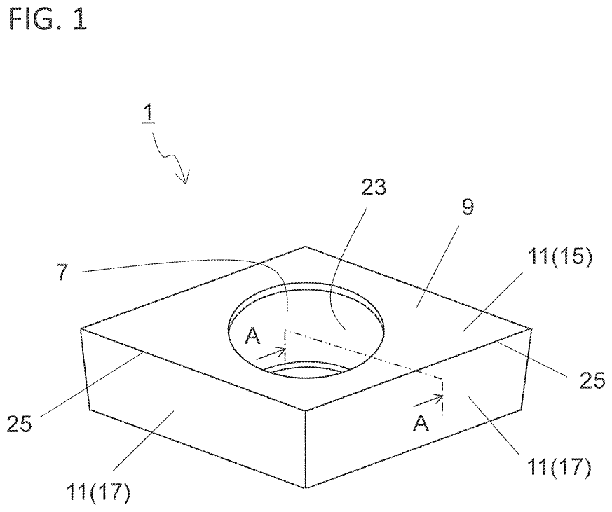

FIG. 2 is an enlarged view of a cross section taken along line A-A in the cutting insert illustrated in FIG. 1;

FIG. 3 is a top view illustrating a cutting tool in a non-limiting embodiment of the present disclosure; and

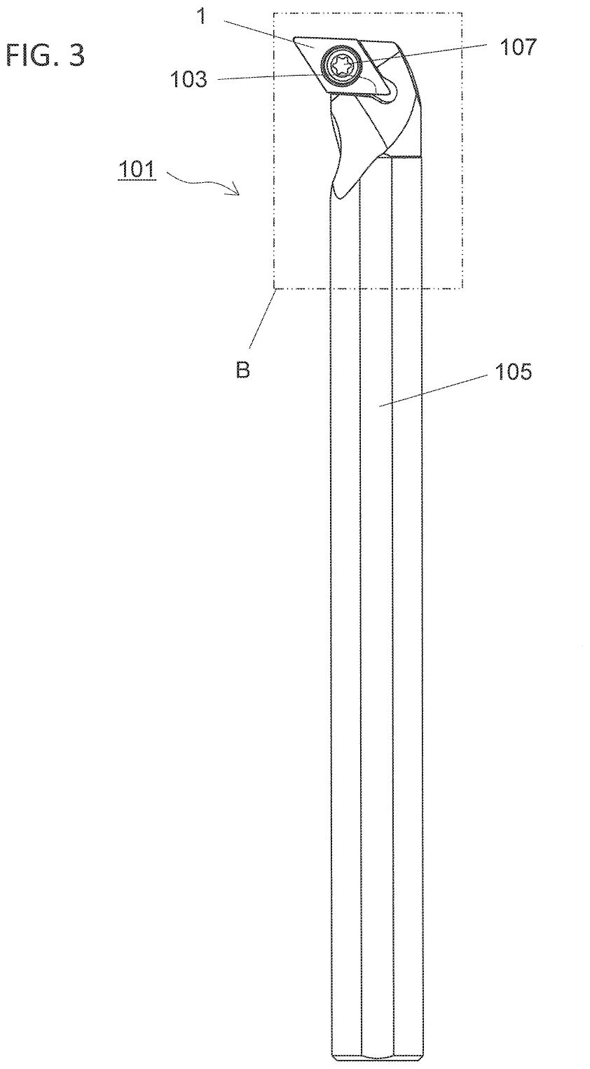

FIG. 4 is an enlarged view of a region B in FIG. 3.

### DETAILED DESCRIPTION

Inserts of various non-limiting aspects of the present disclosure are described in detail below with reference to the drawings. For the sake of description, each of the drawings referred to in the following illustrates, in a simplified form, only main members necessary for describing the various non-limiting embodiments. The cutting insert of the present disclosure are therefore capable of including an arbitrary structural member not illustrated in the drawings referred to.

Dimensions of the members in each of the drawings are not ones which faithfully represent dimensions of actual structural members and dimension ratios of these members.

<Insert>

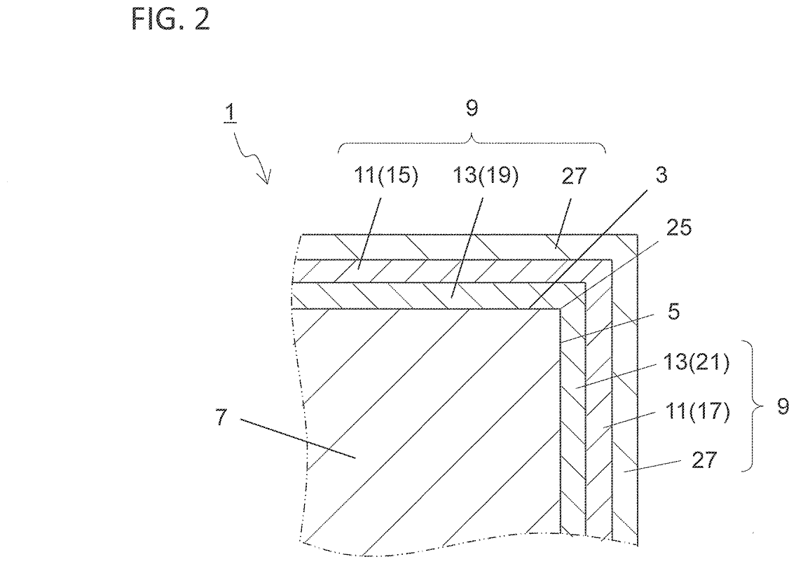

The cutting insert 1 according to a non-limiting embodiment of the present disclosure (hereinafter referred to simply as “the insert 1”) includes a base member including a first surface 3 and a second surface 5 adjacent to the first surface 3, and a coating layer 9 located on a surface of the base member 7 as illustrated in FIG. 2. The coating layer 9 includes a first layer 11 located above the first surface 3 and the second surface 5. The first layer 11 contains α-aluminum oxide. The coating layer 9 further includes a second layer 13 which is located between the base member 7 and the first layer 11 and contains crystals of titanium carbide.

For the sake of convenience, a region of the first layer 11 which is located above the first surface 3 is hereinafter defined as a first region 15, and a region of the first layer 11 which is located above the second surface 5 is hereinafter defined as a second region 17. For the sake of convenience, a region of the second layer 13 which is located between the first surface 3 and the first region 15 is hereinafter defined as a third region 19, and a region of the second layer 13 which is located between the second surface 5 and the second region 17 is hereinafter defined as a fourth region 21. A surface of the coating layer 9 located on the first surface 3 is a so-called rake surface. A surface of the coating layer located on the second surface 5 is a so-called flank surface. When a surface of the first region 15 is an outermost surface of the coating layer 9 in the first surface 3 and when a surface of the second region 17 is an outermost surface of the coating layer 9 in the second surface 5, the surface of the first region 15 and the surface of the second region 17 are respectively indicated and described as the rake surface and the flank surface in some cases.

The first layer 11 contains the α-aluminum oxide as described above in a non-limiting embodiment of the present disclosure. A crystal structure of the α-aluminum oxide is hexagonal crystal. Crystals of the α-aluminum oxide have therefore a polygonal prism shape, such as an approximately hexagonal prism shape, in the first layer 11.

Specifically, an end surface of a polygonal shape in the polygonal prism, for example, a surface corresponding to an end surface of a hexagonal shape is a (001) plane in the crystals of the α-aluminum oxide. The crystals of the α-aluminum oxide have, for example, a shape extending in a direction orthogonal to the (001) plane in a non-limiting embodiment of the present disclosure.

A plurality of the crystals of the α-aluminum oxide exist above the first surface 3 and the second surface 5 so as to constitute the first layer 11. A relationship between the first and second surfaces 3 and 5 and a normal line L1 of the (001) plane of each of the crystals of the α-aluminum oxide is not constant but varies.

When an angle formed by the normal line L1 of the (001) plane of the α-aluminum oxide in the first layer 11 and a normal line L2 of a surface of the base member 7 is taken as a first inclination angle θ1, the first inclination angle θ1 is not constant but varies, and has a distribution.

The distribution of the first inclination angle θ1 is measurable by measurement using a field emission-type scanning electron microscope or measurement using Electron BackScatter Diffraction (EBSD) method.

Of these measurement methods, a non-limiting embodiment of the measurement using the Electron BackScatter Diffraction method is described below. The first inclination angle θ1 is first measured at intervals of 0.1 μm in a range of approximately 40×25 μm² by irradiating electron rays to the first region 15 in a cross-section orthogonal to the surface of the base member 7 in the insert 1. Subsequently, a graph of frequency distribution of the first inclination angle θ1 in the first region 15 is obtainable by dividing the measured first inclination angle θ1 at a pitch of 0.25 degrees, and by counting the number of measurements divided into individual segments. A graph of frequency distribution of the first inclination angle in the second region 17 is also obtainable by applying the same technique to the first inclination angle θ1 in the second region 17.

When an angle formed by the normal line L1 of the (001) plane of the α-aluminum oxide in the first layer 11 and the normal line L2 of the surface of the base member 7 is taken as a first inclination angle θ1, a peak of a distribution of the first inclination angle θ1 in the first region 15 is located at a lower angle side than a peak of a distribution of the first inclination angle θ1 in the second region 17 in the insert 1 of a non-limiting embodiment of the present disclosure.

The insert 1 includes the rake surface having enhanced durability and the flank surface having enhanced durability because the peak of the distribution of the first inclination angle in the first region 15 is located at the lower angle side than the peak of the distribution of the first inclination angle in the second region 17. Each of the rake surface and the flank surface in the insert 1 consequently has the enhanced durability.

A cutting load tends to propagate in an approximately vertical direction relative to the surface of the base member 7 and the surface of the first layer 11 in the rake surface. Compared to the rake surface, a cutting load tends to propagate in a direction inclined relative to the surface of the base member 7 in the flank surface. The peak of the distribution of the first inclination angle in the second region 17 of the flank surface is therefore made smaller than the peak of the distribution of the first inclination angle in the first region 15 of the rake surface, thus leading to the enhanced durability of the rake surface and the flank surface.

The peak of the distribution of the first inclination angle θ1 in the first region 15 may be set to, for example, 0-30°. The peak of the distribution of the first inclination angle θ1 in the first region 15 may have the peak in the direction orthogonal to the surface of the base member 7, namely, at the lower angle side. Hence, the peak of the distribution of the first inclination angle θ1 may have a lower value in the above range, for example, in a range of 0-20°. The peak of the distribution of the first inclination angle θ1 in the second region 17 may be set to, for example, 10-50°. The peak of the distribution of the first inclination angle θ1 in the second region 17 may be 0-30°.

The first region 15 and the second region 17 are different in peak of the distribution of the first inclination angle θ1 in the insert 1 of a non-limiting embodiment of the present disclosure as described above. In other words, the first region 15 and the second region 17 are different in crystal state of the α-aluminum oxide.

For example, coefficient of thermal expansion may be different in some cases in an intersecting portion of the two first layers that are different in state. Therefore, a difference between the first inclination angle θ1 in the first region 15 and the peak of the distribution of the first inclination angle θ1 in the second region 17 may be controlled in a range of 5-20°. Thus, in cases where there is a small difference in state between the first region 15 and the second region 17, the intersecting region of the two is less subject to breakage.

In cases where the peak of the distribution of the first inclination angle θ1 in the first region 15 is located at the lower angle side than the peak of the distribution of the first inclination angle θ1 in the second region 17 and where the peak of the distribution of the first inclination angle θ1 in the first region 15 is greater than the peak of the distribution of the first inclination angle θ1 in the second region 17, the first layer 11 has further enhanced durability for the following reason in a non-limiting embodiment of the present disclosure.

The rake surface (first region 15) is susceptible to a larger cutting load than the flank surface (second region 17). The cutting load is applied to the second region 17 by propagation through an interior of the insert 1, such as the base member 7. A direction of the cutting load applied to the second region 17 is therefore more likely to vary than that in the first region 15.

When the peak of the distribution of the first inclination angle in the first region 15 is relatively great, the rake surface has enhanced durability against the relatively great cutting load applied to the rake surface (first region 15). In other words, because the peak of the distribution of the first inclination angle θ1 in the second region 17 becomes relatively small, a deviation of the distribution of the first inclination angle θ1 in the second region 17 becomes small. Consequently, the enhanced durability can be ensured even for the flank surface (second region 17) in which a direction of the applied cutting load tends to vary. The first layer 11 therefore has further enhanced durability.

Inorganic materials, such as cemented carbide, cermet and ceramics, are usable for a material of the base member 7. The material of the base member 7 is not limited thereto.

Examples of composition of cemented carbide include WC(tungsten carbide)-Co, WC—TiC(titanium carbide)-Co and WC—TiC—TaC(tantalum carbide)-Co. Here, WC, TiC and TaC are hard particles, and Co is a binding phase. The cermet is a sintered composite material obtained by compositing metal into a ceramic ingredient. Specific examples of the cermet include compounds composed mainly of TiC or TiN (titanium nitride).

A shape of the base member 7 is not limited to a specific configuration but settable to an arbitrary shape. The base member 7 has a square plate shape including square-shaped upper and lower surfaces and a side surface located between these two surfaces in the present non-limiting embodiments. At least a part of the upper surface is a surface having a function as the rake surface, and at least a part of the side surface is the flank surface in the present non-limiting embodiments.

The base member 7 includes a through hole 23 extending through the upper surface and the lower surface in a non-limiting embodiment of the present disclosure. The through hole 23 is usable for inserting a fixing member for fixing the insert 1 to a holder. Examples of the fixing member include a screw and a clamp member.

No particular limitation is placed on a size of the base member 7. For example, a length of one side of the upper surface is settable to approximately 3-20 mm, and a height from the upper surface to the lower surface is settable to approximately 5-20 mm in the present non-limiting embodiments.

A cutting edge 25 is located on at least a part of a ridge line part which the rake surface intersects with the flank surface in the base member 7. Because the upper surface is the rake surface and the side surface is the flank surface in the present non-limiting embodiment, the cutting edge 25 is located on at least the part of the ridge line part which the upper surface intersects with the side surface. The cutting edge 25 is used for cutting a workpiece during a cutting process.

The coating layer 9 is located on the surface of the base member 7 and covers at least a part of the surface of the base member 7. The coating layer 9 is intended to improve characteristics, such as wear resistance and chipping resistance, of the insert 1 during the cutting process. The coating layer 9 therefore need not cover all the surface of the base member 7. Alternatively, a part of the surface of the base member 7 may be exposed from the coating layer 9. The coating layer 9 may be located on the first surface 3, the second surface 5 and the ridge line part in the base member 7. For example, in cases where the base member 7 includes the through hole 23, no particular problem occurs even when an inner wall surface of the through hole 23 is not covered with the coating layer 9.

The coating layer 9 includes the first layer 11 as described above and may further include a second layer 13 in a non-limiting embodiment of the present disclosure. No particular limitations are placed on thickness of the coating layer 9 but the thickness is settable to, for example, 3-100 μm. The coating layer 9 may be constituted only by the first layer 11 and the second layer 13, or alternatively may have such a structure that a third layer 27 is laminated on the second layer 13.

The first layer 11 contains α-aluminum oxide. Although x-aluminum oxide is also well known as a crystal of aluminum oxide, the first layer 11 contains α-type crystal instead of x-type crystal. This contributes to enhancing crystal orientation and enhancing durability of the first layer 11.

The second layer 13 contains titanium. Specifically, the second layer 13 contains at least one of titanium carbide, nitride, oxide, carbonitride, carbooxide and oxycarbonitride. The second layer 13 may have a single layer structure or a multilayer laminate structure. The second layer 13 has a laminate structure that a layer containing titanium nitride, a layer containing titanium carbonitride and a layer containing titanium oxycarbonitride are laminated one upon another in the present non-limiting embodiments.

Similarly to, for example, the second layer 13, the third layer 27 contains at least one of titanium carbide, nitride, oxide, carbonitride, carbooxide and oxycarbonitride. Wear resistance of the coating layer 9 can be improved when the coating layer 9 includes the third layer 27 containing a titanium compound. The coating layer 9 includes the third layer 27 containing titanium nitride as a titanium compound in the present non-limiting embodiments.

The second layer 13 may contain titanium carbonitride in a non-limiting embodiment of the present disclosure. The titanium carbonitride has a columnar crystal structure. Crystals of titanium carbonitride grow in a direction orthogonal to a (422) plane and therefore has a columnar shape extending in the direction orthogonal to the (422) plane. The (422) plane of the crystals of the titanium carbonitride is located approximately parallel to the surface of the base member 7 in the present non-limiting embodiments. The crystals of the titanium carbonitride therefore extend toward the direction orthogonal to the surface of the base member 7.

An angle formed by a normal line L3 of the (422) plane of the titanium carbonitride in the second layer 13 and the normal line L2 of the surface of the base member 7 is taken as a second inclination angle θ2. The second layer 13 has improved strength and improved wear resistance when a peak of a distribution of the second inclination angle θ2 in the third region 19 is located at a lower angle side than a peak of a distribution of the second inclination angle θ2 in the fourth region 21.

The first layer 11 has enhanced durability when the peak of the distribution of the first inclination angle 81 in the first region 15 located above the first surface 3 is located at a lower angle side than the peak of the distribution of the first inclination angle θ1 in the second region 17 located above the second surface 5 in the first layer 11. The second layer 13 has enhanced durability when the peak of the distribution of the second inclination angle θ2 in the third region 19 located above the first surface 3 is located at a lower angle side than the peak of the distribution of the second inclination angle θ2 in the fourth region 21 located above the second surface 5 in the second layer 13.

The peak of the distribution of the second inclination angle θ2 in the third region 19 may be set to, for example, 0-40°. The peak of the distribution of the second inclination angle θ2 in the fourth region 21 may be set to, for example, 10-50°.

In cases where the peak of the distribution of the second inclination angle θ2 in the third region 19 is located at the lower angle side than the peak of the distribution of the second inclination angle θ2 in the fourth region 21 and where the peak of the distribution of the second inclination angle θ2 in the third region 19 is greater than the peak of the distribution of the second inclination angle θ2 in the fourth region 21, the strength of the third region 19 is less likely to vary, and fine chipping and shattering of particles are less likely to occur.

In an intersecting portion of the two second layers that are different in state, for example, the second layers that are different in microstructure may intersect with each other to cause breakage. Therefore, a difference between the peak of the distribution of the second inclination angle θ2 in the third region 19 and the peak of the distribution of the second inclination angle θ2 in the fourth region 21 may be controlled in a range of 5-20°. Thus, by reducing the difference in state between the third region 19 and the fourth region 121, an intersecting region of the two is less subject to breakage.

The distribution of the second inclination angle 82 may be evaluated by measurement using a field emission-type scanning electron microscope or measurement using Electron BackScatter Diffraction method, as in the case of the distribution of the first inclination angle θ1.

(Manufacturing Method)

A method of manufacturing the cutting insert 1 in a non-limiting embodiment of the present disclosure is described below.

Firstly, for example, cobalt-containing metal powder and carbon powder are added to and mixed with inorganic powder selected from among tungsten-containing metal carbides, nitrides, carbon nitrides and oxides. A molded body is prepared by molding the above mixed powders into a predetermined shape with the use of a known molding method. Examples of the molding method include press molding, casting molding, extrusion molding and cold isostatic press molding. The base member 7 is manufactured by sintering the molded body in vacuum or non-oxidization atmosphere.

Subsequently, the second layer 13 on the base member 7 is deposited on a surface of the above-mentioned member by chemical vapor deposition (CVD) method.

Firstly, a first mixed gas, which is used as a reaction gas, is prepared by mixing 0.5-10 vol % of titanium tetrachloride (TiCl₄) gas and 10-60 vol % of nitrogen (N₂) gas together with hydrogen (H₂) gas. A layer containing titanium nitride (TiN) is deposited by introducing the first mixed gas into a chamber.

Subsequently, a second mixed gas is prepared by mixing 0.5-10 vol % of titanium tetrachloride (TiCl₄) gas, 5-60 vol % of nitrogen (N₂) gas and 0.1-3 vol % of acetonitrile (CH₃CN) gas together with hydrogen (H₂) gas. A layer containing MT-titanium carbonitride is deposited by introducing the second mixed gas into the chamber.

A layer containing HT-titanium carbonitride in the second layer 13 is then deposited. A third mixed gas is prepared in the present non-limiting embodiments by mixing 1-4 vol % of titanium tetrachloride (TiCl₄) gas, 5-20 vol % of nitrogen (N₂) gas and 0.1-10 vol % of methane (CH₄) gas together with hydrogen (H₂) gas. The layer containing HT-titanium carbonitride is deposited by introducing the third mixed gas into the chamber.

Subsequently, a layer containing titanium oxycarbonitride (TiCNO) in the second layer 13 is prepared. A fourth mixed gas is prepared by mixing 3-15 vol % of titanium tetrachloride (TiCl₄) gas, 3-10 vol % of methane (CH₄) gas, 0-25 vol % of nitrogen (N₂) gas, 0.5-2 vol % of carbon monoxide (CO) gas and 0-3 vol % of aluminum trichloride (AlCl₃) gas together with hydrogen gas (H₂) gas. A layer containing titanium oxycarbonitride is deposited by introducing the fourth mixed gas into the chamber.

A first layer 11 containing aluminum oxide is then deposited. Alternatively, a crystal nucleus of aluminum oxide may be formed first when depositing the first layer 11 containing α-aluminum oxide. A fifth mixed gas is prepared by mixing 5-10 vol % of aluminum trichloride (AlCl₃) gas, 0.1-1 vol % of hydrogen chloride (HCl) gas and 0.1-5 vol % of carbon dioxide (CO₂) gas together with hydrogen gas (H₂). The above-mentioned nucleus is formed by introducing the fifth mixed gas into the chamber.

Subsequently, a sixth mixed gas is prepared by mixing 5-15 vol % of aluminum trichloride (AlCl₃) gas, 0.5-2.5 vol % of hydrogen chloride (HCl) gas, 0.5-5 vol % of carbon dioxide (CO₂) gas and 0.1-1 vol % of hydrogen sulfide (H₂S) gas together with hydrogen (H₂) gas. A first layer 11 containing aluminum oxide is deposited by introducing the sixth mixed gas into the chamber.

In the step of preparing the base member 7 or the step of depositing the second layer 13, as necessary, a polishing process or a honing process may be applied to a surface of the base member 7 or the second layer 13. For example, a surface of the third region 19 located above the first surface 3 becomes relatively smooth when the above process is carried out so that an arithmetic mean roughness of the surface of the third region 19 in the second layer 13 is smaller than an arithmetic mean roughness of a surface of the fourth region 21 in the second layer 13.

Consequently, when depositing the first layer 11, the orientation of the crystals of the α-aluminum oxide tends to become uniform in the first region 15 located above the third region 19. It is therefore easier to ensure that a peak of the distribution of the first inclination angle 81 in the first region 15 is located at the lower angle side.

For example, the second surface 5 in the base member 7 becomes relatively smooth when the polishing process or honing process is carried out in the step of preparing the base member 7 so that an arithmetic mean roughness in the second surface 5 is smaller than an arithmetic mean roughness in the first surface 3. Consequently, when depositing the second layer 13, the orientation of the crystals of the titanium carbonitride tends to become uniform in the fourth region 21. It is therefore easier to ensure that a peak of the distribution of the second inclination angle θ2 in the fourth region 21 is located at a lower angle side. In this case, the polishing process or honing process may be reapplied to the surface of the second layer 13 in the step of depositing the second layer 13. As long as the surface of the third region 19 has a smaller arithmetic surface roughness than the fourth region 21 by applying the above process to the second layer 13, it is easier to ensure that a peak of the distribution of the first inclination angle θ1 in the first region 15 is located at a lower angle side.

A layer containing titanium nitride (TiN) is further deposited in the present non-limiting embodiments. A seventh mixed gas is prepared by mixing 0.1-10 vol % of titanium tetrachloride (TiCl₄) gas and 10-60 vol % of nitrogen (N₂) gas together with hydrogen (H₂) gas. A layer containing titanium nitride is deposited by introducing the seventh mixed gas into the chamber.

Thereafter, as necessary, a polishing process is applied to a portion of the surface of the deposited coating layer 9 at which the cutting edge 25 is located. By carrying out the polishing process, welding of a workpiece onto the cutting edge 25 is less likely to occur, thus leading to the insert 1 having excellent fracture resistance.

The above manufacturing method is one of methods for manufacturing the insert 1 of the present non-limiting embodiments. Hence, there is no intention to limit the insert 1 of a non-limiting embodiment of the present disclosure to ones which are manufactured by the above manufacturing method.

<Cutting Tool>

A cutting tool 101 in a non-limiting embodiment of the present disclosure is described below with reference to the drawings.

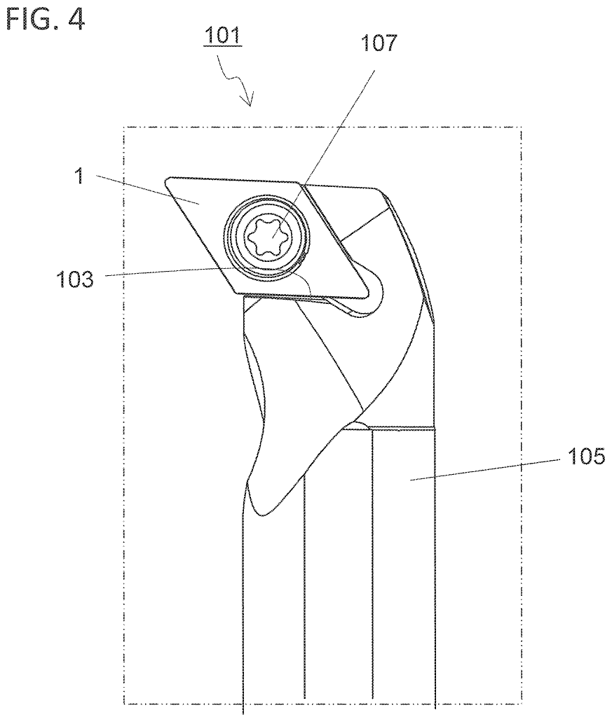

As illustrated in FIGS. 4 and 5, the cutting tool 101 of a non-limiting embodiment of the present disclosure is a bar-shaped body extending from a first end (an upper side in the drawings) toward a second end (a lower side in the drawings). The cutting tool 101 includes a holder 105 having a pocket 103 at a side of the first end, and the insert 1 located at the pocket 103. The insert 1 is attached so that a portion of the ridge line which serves as a cutting edge is protruded from a front end of the holder 105 in the cutting tool 101 of the present non-limiting embodiments.

The pocket 103 is a portion to which the insert 1 is attached. The pocket 103 includes a seating surface parallel to a lower surface of the holder 105, and a constraining side surface being inclined relative to the seating surface. The pocket 103 opens at a side of the first end of the holder 105.

The insert 1 is located at the pocket 103. The lower surface of the insert 1 may be directly contacted with the pocket 103. Alternatively, a sheet may be held between the insert 1 and the pocket 103.

The insert 1 is attached so that a portion of the ridge line which is used as the cutting edge protrudes outward from the holder 105. The insert 1 is attached to the holder 105 by a screw 107 in the present non-limiting embodiments. Specifically, screw portions are screwed together by inserting the screw 107 into the through hole of the insert 1, and by inserting a front end of the screw 107 into a screw hole (not illustrated) formed in the pocket 103. Thus, the insert is attachable to the holder 105.

As a material of the holder 105, for example, steel and cast iron are usable. Of these materials, high toughness steel may be usable in another non-limiting embodiment.

Various non-limiting embodiments of the present disclosure illustrate and describe the cutting tools used in a so-called turning process. Examples of the turning process include inner diameter machining, outer diameter machining and grooving process. The cutting tools are not limited to ones which are usable in the turning processes. For example, the insert 1 of the above non-limiting embodiments may be applied to cutting tools usable in a milling process.

### DESCRIPTION OF THE REFERENCE NUMERALS

1 cutting insert (insert)
3 first surface
5 second surface
7 base member
9 coating layer
11 first layer
13 second layer
15 first region
17 second region
19 third region
21 fourth region
23 through hole
25 cutting edge
27 third layer
101 cutting tool
103 pocket
105 holder
107 screw

1. A cutting insert, comprising:
a base member comprising a first surface and a second surface adjacent to the first surface, and a coating layer located on a surface of the base member, wherein
the coating layer comprises a first layer being located above the first surface and the second surface and comprising α-aluminum oxide,
the first layer comprises a first region located above the first surface, and a second region located above the second surface, and
when an angle formed by a normal line of a (001) plane being a crystal plane of the α-aluminum oxide in the first layer and a normal line of the surface of the base member is taken as a first inclination angle, a peak of a distribution of the first inclination angle in the first region is located at a lower angle side than a peak of a distribution of the first inclination angle in the second region.

2. The cutting insert according to claim 1, wherein
the peak of the distribution of the first inclination angle is located in a range of 0-30° in the first region.

3. The cutting insert according to claim 2, wherein
the peak of the distribution of the first inclination angle is located in a range of 10-50° in the second region.

4. The cutting insert according to claim 1, wherein
a difference between the peak of the distribution of the first inclination angle in the first region and the peak of the distribution of the first inclination angle in the second region is 5-20°.

5. The cutting insert according to claim 1, wherein
the peak of the distribution of the first inclination angle in the first region is greater than the peak of the distribution of the first inclination angle in the second region.

6. The cutting insert according to claim 1, wherein
the coating layer comprises a second layer being located between the base member and the first layer and comprising crystals of titanium carbonitride,
the second layer comprises a third region located between the first surface and the first region, and a fourth region located between the second surface and the second region, and
when an angle formed by a normal line of a (422) plane being a crystal plane of the titanium carbonitride in the second layer and the normal line of the surface of the base member is taken as a second inclination angle, a peak of a distribution of the second inclination angle in the third region is located at a lower angle side than a peak of a distribution of the second inclination angle in the fourth region.

7. The cutting insert according to claim 6, wherein
the peak of the distribution of the second inclination angle is located in a range of 0-40° in the third region.

8. The cutting insert according to claim 7, wherein
the peak of the distribution of the second inclination angle is located in a range of 10-50° in the fourth region.

9. The cutting insert according to claim 6, wherein
a difference between the peak of the distribution of the second inclination angle in the third region and the peak of the distribution of the second inclination angle in the fourth region is 5-20°.

10. The cutting insert according to claim 6, wherein
the peak of the distribution of the second inclination angle in the third region is greater than the peak of the distribution of the second inclination angle in the fourth region.

11. A cutting tool, comprising:
a holder comprising a bar-shaped body extending from a first end toward a second end and comprising a pocket at a side of the first end; and
the cutting insert according to claim 1, the cutting insert being located at the pocket in the holder.
